(19) United States
(12) Patent Application Publication
(10) Pub. No.: US 2021/0261790 A1
(43) Pub. Date: Aug. 26, 2021

(54) COATED SYSTEMS FOR HYDROGEN

(71) Applicant: SILCOTEK CORP., Bellefonte, PA (US)

(72) Inventors: Geoffrey K. WHITE, State College, PA (US); Nikolis Austin SNYDER, Bellefonte, PA (US); Nicholas Peter DESKEVICH, Hollidaysburg, PA (US); Gary A. BARONE, State College, PA (US); David A. SMITH, Bellefonte, PA (US); Lucas D. PATTERSON, Altoona, PA (US); Martin E. HIGGINS, Bellefonte, PA (US)

(21) Appl. No.: 17/306,586

(22) Filed: May 3, 2021

(51) Int. Cl. C09D 5/08; C23C 16/34; C23C 16/40; C23C 16/32; C23C 16/54; C23C 16/46; C09D 1/00; C09D 183/04; C09D 183/16

(52) U.S. Cl. CPC C09D 5/08; C23C 16/345; C23C 16/401; C23C 16/325; C09D 183/16; C23C 16/46; C09D 1/00; C09D 183/04; C23C 16/545

(57) ABSTRACT

A coated system for containing or conveying a hydrogen-containing fluid including a hydrogen susceptible metallic substrate and a coating on the hydrogen susceptible metallic substrate. The hydrogen-containing fluid is in contact with the coating and the coating reduces or eliminates the effect of hydrogen on the hydrogen susceptible metallic substrate. A coating process for coating a hydrogen susceptible metallic substrate is also disclosed.

### FIELD OF THE INVENTION

The present invention is directed to coated systems for containing or conveying hydrogen. More particularly, the present invention is directed to a coated system and method that provides a coating that reduces or eliminates the effect of hydrogen on hydrogen susceptible metallic substrates.

### BACKGROUND OF THE INVENTION

The hydrogen economy presents new technical challenges to overcome. Some properties able to meet such challenges exist in technologies that have been incompatible with specific needs of the hydrogen economy. However, there essentially are infinite material science solutions to consider, so predictably and successfully selecting those solutions that are able to meet such needs while being compatible remains extremely challenging. For example, the hydrogen economy suffers from the problem of unacceptable weight to volume ratios of current hydrogen storage. In addition, components for hydrogen storage and for hydrogen vehicles are too heavy or too large to provide economical operation.

Known systems for use in hydrogen environments include coated components having a thermal chemical vapor deposition coating produced in an enclosed oven limited to having a maximum dimension of about 2 meters. For example, the Silconert® coating process and the Sulfinert® coating process, both available from SilcoTek Corporation, Bellefonte, Pa., have been used for coating components for hydrogen fuel sampling, as described in CHALLENGES IN HYDROGEN FUEL SAMPLING DUE TO CONTAMINANT BEHAVIOUR IN DIFFERENT GAS CYLINDERS, A. S. O. Morris, et al., International Journal of Hydrogen Energy, Feb. 28, 2021 (“Morris”), the entirety of which is incorporated by reference. However, fuel sampling is relatively close in nature to common analytical instrumentation techniques that regularly employ such coatings, thereby limiting the motivation to use such coating processes for other needs in the hydrogen economy.

Known systems have prevented hydrogen and deuterium out-gassing by using coated components having a thermal chemical vapor deposition coating produced in an enclosed oven limited to having a maximum dimension of about 2 meters. For example, the Silcosteel® coating process, available from SilcoTek Corporation, Bellefonte, Pa., has been used for coating stainless steel cylinders, as described in ON-LINE MICRO GC TESTING PROTIUM ANALYSIS IN DT FUELS FROM TCAP PRODUCTS, Weiwei Wang, et al., Fusion Engineering and Design 170, 2021 (“Wang”), the entirety of which is incorporated by reference. Wang limits the use of components from the Silcosteel® coating process to analytical systems and does not contemplate broader use, although not intending to be bound by theory, perhaps due to materials in the nuclear industry being subject to ASME standards on metal substrates, which create incompatibilities for coated substrates.

Other known systems have addressed hydrogen fuel quality, for example, under ISO 14687 and/or SAE J2719, by relying upon the Dursan® coating process or SilcoNert® 2000 coating process, each available from SilcoTek Corporation, Bellefonte, Pa., as critical surfaces for handling fluid contaminants, such as water. Specifically, A2.3.1: REVIEW OF THE AVAILABLE PASSIVATION TREATMENTS FOR GAS CYLINDERS, Metrology for Hydrogen Vehicles, Jun. 6, 2018 (“EURAMET”), the entirety of which is incorporated by reference. Such concepts have been publicly disclosed as potentially synergistic with automotive applications, such as, fuel lines, fuel cells, tubing, for example, in ARE NON REACTIVE SILCOTEK.COM: COATINGS NEEDED FOR HYDROGEN ANALYSIS, M. A. Higgins, Mar. 9, 2019 (“Higgins”), the entirety of which is incorporated by reference. However, such systems described in Higgins have remained limited to components that are coated within an enclosed oven having a maximum dimension of 2 meters, thereby limiting the applicability in large-scale systems necessary for meeting certain needs within the hydrogen economy. Furthermore, hydrogen analysis differs from hydrogen use within the hydrogen economy in that there are many additional technological challenges that remain unmet.

A coating system including a passivated surface for exposure to corrosive substances or vacuum environments is described in U.S. Pat. Pub. No. 2004/0175578A1 (“the '578 Publication”), published Sep. 9, 2004, for “Method For Chemical Vapor Deposition Of Silicon On To Substrates For Use In Corrosive And Vacuum Environments.” The '578 Publication discloses that the passivated surface formed by the coating process provides resistance to offgassing, outgassing and hydrogen permeation. The hydrogen permeation resistance reduces hydrogen permeation from atomic hydrogen-containing corrosive substances, including organo-sulfurs, hydrogen sulfide, alcohols, acetates, metal hydrides, hydrochloric acid, nitric acid, or sulfuric acid and aqueous salts. However, the coating system described in the '578 Publication is limited to small, analytical equipment capable of maintaining a vacuum that is coated within an enclosed oven having a maximum dimension of approximately 2 meters, thereby limiting the potential substrates capable of being coated. Furthermore, the coating system of the '578 Publication fails to provide a large-scale solution for hydrogen susceptible metallic substrates that provides resistance to hydrogen-containing fluids.

The United Nations has acknowledged inadequacies in the existing infrastructure and technology to support the hydrogen economy, for example, in UNITED NATIONS ECONOMIC AND SOCIAL COUNCIL, Economic Commission for Europe—Committee on Sustainable Energy, Twenty-ninth session (Sep. 15, 2020) (“UN”), which is incorporated by reference in its entirety. UN states that electrolyser development is needed, for example, with fuel cells. UN further states that hydrogen transportation requires development. In addition, UN asserts that market change requires shifting of production for carbon-free or low-carbon steel, ammonia, methanol, and other chemical products. UN recommends that the energy industry retrofit and repurpose current gas infrastructure for hydrogen, including hydrogen-only pipelines, despite existing material science solutions for hydrogen being incompatible with such infrastructure.

The Pipeline Research Council International, Incorporated emphasizes the long-felt but unmet needs associated with transitioning to hydrogen-only pipelines and other hydrogen-compatible technology within EMERGING FUELS—HYDROGEN SOTA, GAP ANALYSIS, FUTURE PROJECT ROADMAP, K. Domptail, et al., Catalog No. PR-720-20603-R01, Sep. 18, 2020 (“PRCI”), the entirety of which is incorporated by reference. PRCI explains that technology is insufficient in meeting needs regarding pipeline integrity, safety, end-use equipment, metering/gas quality, network management and compression, inspection and maintenance, hydrogen-natural gas separation, and underground gas storage. PRCI expressly identifies unmet needs associated within each area.

Coated systems for hydrogen that solve the technical challenges of the hydrogen economy and provides the ability to utilize a larger range of materials in equipment to contain or convey hydrogen-containing fluids would be desirable in the art.

### BRIEF DESCRIPTION OF THE INVENTION

In an embodiment, a coated system for containing or conveying a hydrogen-containing fluid includes a hydrogen susceptible metallic substrate and a coating on the hydrogen susceptible metallic substrate. The hydrogen-containing fluid is in contact with the coating and the coating reduces or eliminates the effect of hydrogen on the hydrogen susceptible metallic substrate.

In an embodiment, a coating process includes providing a coated coil formed from a hydrogen susceptible metallic substrate having a coating on an inside surface and an outside surface. The coated coil is uncoiled and reshaped with one or more forming devices to form a shaped coated coil. The shaped coated coil is welded using a welder to form a cylinder. The cylinder is re-coated on an interior portion at a heated zone. The coating on the coated coil and formed from the re-coating reduces or eliminates the effect of hydrogen on the hydrogen susceptible metallic substrate.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is schematic perspective view of a seaming operation and thermal chemical vapor deposition process, according to an embodiment of the disclosure.

FIG. 2 is a schematic perspective view of a thermal chemical vapor deposition process of coating a pipe/tube, according to an embodiment of the disclosure.

FIG. 3 is a schematic perspective view of a thermal chemical vapor deposition process of coating a pipe/tube, according to another embodiment of the disclosure.

FIG. 4 is a schematic perspective view of a thermal chemical vapor deposition process of coating a pipe/tube, according to another embodiment of the disclosure.

FIG. 5 is a schematic perspective view of a thermal chemical vapor deposition process of an area of joined pipes/tubes, according to an embodiment of the disclosure.

### DETAILED DESCRIPTION OF THE INVENTION

Provided are coated systems and components for hydrogen, as well as, processes of transporting, storing, and using hydrogen in conjunction with such coated systems and components that address the drawbacks of the prior art identified above, all of which is incorporated by reference in their entirety. As used herein, the term “hydrogen” refers to dihydrogen, such as H₂ gas or liquid. The term is not intended to encompass atomic hydrogen, for example, in hydrochloric acid. Embodiments of the present disclosure, for example, in comparison to concepts failing to include one or more of the features disclosed herein, permit use of steel in conjunction with previously-considered incompatible fluids (for example, hydrogen, hydrogen-containing blends, impure hydrogen, and/or liquids/gases that corrode steel), or a combination thereof. The coated systems, according to the present disclosure, provide reduced or eliminated incompatibility of materials susceptible to hydrogen embrittlement, hydrogen-induced cracking, hydrogen-induced corrosion, or otherwise have limitations on hydrogen blending/loading ratios, availability of odorants, pipeline/valve leaks not present with other gases, such as propane. In addition, the coated systems, according to the present disclosure, provide a desirable weight to volume ratio for components that contain or convey hydrogen-containing fluids, such as long-distance pipelines. In addition, the low weight to volume ratios of the coated systems, according to the present disclosure, provide lightweight storage materials suitable for a variety of applications, including hydrogen vehicles. Further, embodiments of the present disclosure reduce the costs and improve the efficiency of hydrogen production. Further still, embodiments of the present disclosure permit coating of large components, including components having a dimension greater than 2 meters.

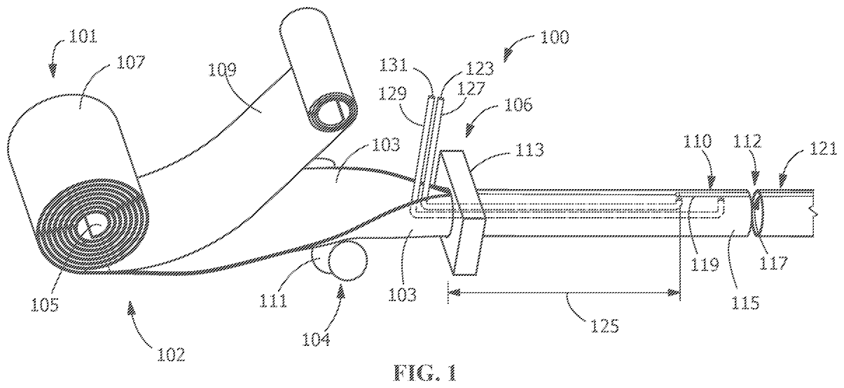

Referring to FIG. 1, in one embodiment, a seaming operation 100 includes a coated coil 101 having a coating 103 on an inside surface 105 and an outside surface 107, separated by an insert 109 removeable during operation of the seaming operation 100. The seaming operation 100 includes uncoiling (step 102) the coated coil 101, reshaping (step 104) using one or more forming devices 111, and welding (step 106) using a welder 113 to secure a profile of a pipe/tube 115 that is re-coated (step 110), for example, on an interior portion 117 extending over the heated zone 119 from the welding (step 106). The pipe/tube 115 is then cut (step 112) to form a cut pipe/tube 121 or coiled to form coiled tubing (not shown), each of which are embodiments of a portion of or the entirety of a coated system capable of being positioned in a hydrogen application according to the disclosure. The formation of the cut pipe/tube 121 via the continuous process permits the coating of large components, including components larger than 2 meters, or 5 meters, or 10 meters, or 50 meters in length.

The coil 101 is preferably formed of a hydrogen susceptible metallic substrate. “Hydrogen susceptible metallic substrate”, as utilized herein, is a substrate containing at least one metal and having the property of being susceptible to degradation in the presence of hydrogen. In particular, the substrate includes a material that degrades by a physical or chemical mechanism resulting from contact with molecular hydrogen or dihydrogen, such as hydrogen embrittlement, corrosion (such as hydride stress corrosion), hydrogen stress cracking, hydrogen blistering, high temperature hydrogen attack or any other mechanism that results in loss in ductility, reduction in strength, reduction in fracture toughness, loss of containment stability and/or enhanced crack growth by mechanisms, such as hydrogen-induced cracking or blistering.

Suitable substrates for use as the hydrogen susceptible metallic substrate include ferrous-based alloys (for example, low-carbon and low-alloy steel, or high strength steel), non-ferrous-based alloys, nickel or cobalt-based alloys (for example, Hastelloys or MP35N), stainless steels (for example, martensitic, austenitic or duplex stainless steel), aluminum-containing materials (for example, alloys, Alloy 6061, aluminum), composite metals, or combinations thereof.

The hydrogen susceptible metallic substrate may be a material that is tempered or non-tempered, has grain structures that are equiaxed, directionally-solidified, and/or single crystal, has amorphous or crystalline structures, is a foil, fiber, a cladding, and/or a film. In an alternative embodiment, a portion of the hydrogen susceptible metallic substrate is replaced or otherwise integrated with a non-hydrogen susceptible material, in a combined structure, such as a composite material. Suitable non-hydrogen materials include, but are not limited to, non-hydrogen susceptible metallic materials, ceramics, glass, ceramic matrix composites, or a combination thereof.

In one embodiment, the hydrogen susceptible metallic substrate has a first iron concentration and a first chromium concentration, the first iron concentration being greater than the first chromium concentration. For example, suitable values for the first iron concentration include, but are not limited to, by weight, greater than 50%, greater than 60%, greater than 66%, greater than 70%, between 66% and 74%, between 70% and 74%, or any suitable combination, sub-combination, range, or sub-range therein. Suitable values for the first chromium concentration include, but are not limited to, by weight, greater than 10.5%, greater than 14%, greater than 16%, greater than 18%, greater than 20%, between 14% and 17%, between 16% and 18%, between 18% and 20%, between 20% and 24%, or any suitable combination, sub-combination, range, or sub-range therein. In other embodiments, the hydrogen susceptible metallic substrate is or includes low alloy steel containing carbon steel mainly comprising C, Si, Mn, Al, and the like, and alloy elements such as Nb, Cu, Ni, Cr, Mo, V, Ti, and the like, in 5% or less by weight in total for the purpose of improving strength and toughness.

In one embodiment, the hydrogen susceptible metallic substrate is a Co—Ni—Cr—Mo alloy, such as MP35N. In a further embodiment, the hydrogen susceptible metallic substrate is or includes a composition, by weight, of between 33.0% and 37.0% nickel, between 19.0% and 21.0% chromium, between 9.0% and 10.5% molybdenum, up to 0.025% carbon, up to 0.15% manganese, up to 0.15% silicon, up to 0.015% phosphorus, up to 0.010% sulfur, up to 1.0% iron, up to 1.0% titanium, and a balance cobalt.

In one embodiment, the hydrogen susceptible metallic substrate is or includes a composition, by weight, of up to 0.08% carbon, between 18% and 20% chromium, up to 2% manganese, between 8% and 10.5% nickel, up to 0.045% phosphorus, up to 0.03% sulfur, up to 1% silicon, and a balance of iron (for example, between 66% and 74% iron).

In one embodiment, the hydrogen susceptible metallic substrate is or includes a composition, by weight, of up to 0.08% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the hydrogen susceptible metallic substrate is or includes a composition, by weight, of up to 0.03% carbon, up to 2% manganese, up to 0.045% phosphorus, up to 0.03% sulfur, up to 0.75% silicon, between 16% and 18% chromium, between 10% and 14% nickel, between 2% and 3% molybdenum, up to 0.1% nitrogen, and a balance of iron.

In one embodiment, the hydrogen susceptible metallic substrate is or includes a composition, by weight, of between 14% and 17% chromium, between 6% and 10% iron, between 0.5% and 1.5% manganese, between 0.1% and 1% copper, between 0.1% and 1% silicon, between 0.01% and 0.2% carbon, between 0.001% and 0.2% sulfur, and a balance nickel (for example, 72%).

In one embodiment, the hydrogen susceptible metallic substrate is or includes a composition, by weight, of between 20% and 24% chromium, between 1% and 5% iron, between 8% and 10% molybdenum, between 10% and 15% cobalt, between 0.1% and 1% manganese, between 0.1% and 1% copper, between 0.8% and 1.5% aluminum, between 0.1% and 1% titanium, between 0.1% and 1% silicon, between 0.01% and 0.2% carbon, between 0.001% and 0.2% sulfur, between 0.001% and 0.2% phosphorus, between 0.001% and 0.2% boron, and a balance nickel (for example, between 44.2% and 56%).

In one embodiment, the hydrogen susceptible metallic substrate is or includes a composition, by weight, of between 20% and 23% chromium, between 4% and 6% iron, between 8% and 10% molybdenum, between 3% and 4.5% niobium, between 0.5% and 1.5% cobalt, between 0.1% and 1% manganese, between 0.1% and 1% aluminum, between 0.1% and 1% titanium, between 0.1% and 1% silicon, between 0.01% and 0.5% carbon, between 0.001% and 0.02% sulfur, between 0.001% and 0.02% phosphorus, and a balance nickel (for example, 58%).

In one embodiment, the hydrogen susceptible metallic substrate is or includes a composition, by weight, of between 25% and 35% chromium, between 8% and 10% iron, between 0.2% and 0.5% manganese, between 0.005% and 0.02% copper, between 0.01% and 0.03% aluminum, between 0.3% and 0.4% silicon, between 0.005% and 0.03% carbon, between 0.001% and 0.005% sulfur, and a balance nickel (for example, 59.5%).

In one embodiment, the hydrogen susceptible metallic substrate is or includes a composition, by weight, of between 17% and 21% chromium, between 2.8% and 3.3% iron, between 4.75% and 5.5% niobium, between 0.5% and 1.5% cobalt, between 0.1% and 0.5% manganese, between 0.2% and 0.8% copper, between 0.65% and 1.15% aluminum, between 0.2% and 0.4% titanium, between 0.3% and 0.4% silicon, between 0.01% and 1% carbon, between 0.001 and 0.02% sulfur, between 0.001 and 0.02% phosphorus, between 0.001 and 0.02% boron, and a balance nickel (for example, between 50% and 55%).

In one embodiment, the hydrogen susceptible metallic substrate is or includes a composition, by weight, of between 2% and 3% cobalt, between 15% and 17% chromium, between 5% and 17% molybdenum, between 3% and 5% tungsten, between 4% and 6% iron, between 0.5% and 1% silicon, between 0.5% and 1.5% manganese, between 0.005 and 0.02% carbon, between 0.3% and 0.4% vanadium, and a balance nickel.

In one embodiment, the hydrogen susceptible metallic substrate is or includes a composition, by weight, of up to 0.15% carbon, between 3.5% and 5.5% tungsten, between 4.5% and 7% iron, between 15.5% and 17.5% chromium, between 16% and 18% molybdenum, between 0.2% and 0.4% vanadium, up to 1% manganese, up to 1% sulfur, up to 1% silicon, up to 0.04% phosphorus, up to 0.03% sulfur, and a balance nickel.

In one embodiment, the hydrogen susceptible metallic substrate is or includes a composition, by weight, of up to 2.5% cobalt, up to 22% chromium, up to 13% molybdenum, up to 3% tungsten, up to 3% iron, up to 0.08% silicon, up to 0.5% manganese, up to 0.01% carbon, up to 0.35% vanadium, and a balance nickel (for example, 56%).

In one embodiment, the hydrogen susceptible metallic substrate is or includes a composition, by weight, of between 1% and 2% cobalt, between 20% and 22% chromium, between 8% and 10% molybdenum, between 0.1% and 1% tungsten, between 17% and 20% iron, between 0.1% and 1% silicon, between 0.1% and 1% manganese, between 0.05 and 0.2% carbon, and a balance nickel.

In one embodiment, the hydrogen susceptible metallic substrate is or includes a composition, by weight, of between 0.01% and 0.05% boron, between 0.01% and 0.1% chromium, between 0.003% and 0.35% copper, between 0.005% and 0.03% gallium, between 0.006% and 0.8% iron, between 0.006% and 0.3% magnesium, between 0.02% and 1% silicon+iron, between 0.006% and 0.35% silicon, between 0.002% and 0.2% titanium, between 0.01% and 0.03% vanadium+titanium, between 0.005% and 0.05% vanadium, between 0.006% and 0.1% zinc, and a balance aluminum (for example, greater than 99%)

In one embodiment, the hydrogen susceptible metallic substrate is or includes a composition, by weight, of between 0.05% and 0.4% chromium, between 0.03% and 0.9% copper, between 0.05% and 1% iron, between 0.05% and 1.5% magnesium, between 0.5% and 1.8% manganese, between 0.5% and 0.1% nickel, between 0.03% and 0.35% titanium, up to 0.5% vanadium, between 0.04% and 1.3% zinc, and a balance aluminum (for example, between 94.3% and 99.8%).

In one embodiment, the hydrogen susceptible metallic substrate is or includes a composition, by weight, of between 0.0003% and 0.07% beryllium, between 0.02% and 2% bismuth, between 0.01% and 0.25% chromium, between 0.03% and 5% copper, between 0.09% and 5.4% iron, between 0.01% and 2% magnesium, between 0.03% and 1.5% manganese, between 0.15% and 2.2% nickel, between 0.6% and 21.5% silicon, between 0.005% and 0.2% titanium, between 0.05% and 10.7% zinc, and a balance aluminum (for example, between 70.7% to 98.7%).

In one embodiment, the hydrogen susceptible metallic substrate is or includes a composition, by weight, of between 0.15% and 1.5% bismuth, between 0.003% and 0.06% boron, between 0.03% and 0.4% chromium, between 0.01% and 1.2% copper, between 0.12% and 0.5% chromium +manganese, between 0.04% and 1% iron, between 0.003% and 2% lead, between 0.2% and 3% magnesium, between 0.02% and 1.4% manganese, between 0.05% and 0.2% nickel, between 0.5% and 0.5% oxygen, between 0.2% and 1.8% silicon, up to 0.05% strontium, between 0.05% and 2% tin, between 0.01% and 0.25% titanium, between 0.05% and 0.3% vanadium, between 0.03% and 2.4% zinc, between 0.05% and 0.2% zirconium, between 0.150% and 0.2% zirconium+titanium, and a balance of aluminum (for example, between 91.7% and 99.6%).

In one embodiment, the hydrogen susceptible metallic substrate is or includes a composition, by weight, of between 0.4% and 0.8% silicon, up to 0.7% iron, between 0.15% and 0.4% copper, up to 0.15% manganese, between 0.8% and 1.2% magnesium, between 0.04% and 0.35% chromium, up to 0.25% zinc, up to 0.15% titanium, optional incidental impurities (for example, at less than 0.05% each, totaling less than 0.15%), and a balance of aluminum (for example, between 95% and 98.6%).

In one embodiment, the hydrogen susceptible metallic substrate is or includes a composition, by weight, of between 11% and 13% silicon, up to 0.6% impurities/residuals, and a balance of aluminum.

In one embodiment, the hydrogen susceptible metallic substrate is or includes a composition, by weight, of between 0.7% and 1.1% magnesium, between 0.6% and 0.9% silicon, between 0.2% and 0.7% iron, between 0.1% and 0.4% copper, between 0.05% and 0.2% manganese, 0.02% and 0.1% zinc, 0.02% and 0.1% titanium, and a balance aluminum. In a further embodiment, the hydrogen susceptible metallic substrate is Alloy 6061.

In one embodiment, the coated coil 101 is consistent with that which is disclosed in U.S. Patent Publication No. 2019/0218661, filed Jan. 16, 2019, and entitled SPOOLED ARRANGEMENT AND PROCESS OF PRODUCING A SPOOLED ARRANGEMENT, commonly assigned with the present application. Suitable compositions of the coating 103 include the coating 103 being an amorphous silicon coating, a silicon-oxygen-carbon-containing coating, a silicon-nitrogen-containing coating, a silicon-fluorine-carbon-containing coating, or a combination thereof. Further embodiments include the coating 103 having a carbon functionalization. In one embodiment, the coating 103 is the amorphous silicon coating with the amorphous silicon being at a composition, by weight, of at least 50%. In one embodiment, the coating 103 is the silicon-oxygen-carbon-containing coating with silicon, oxygen, and carbon each being at a composition, by weight, of at least 10%. In one embodiment, the coating 103 is the silicon-nitrogen-containing coating with silicon and nitrogen each being at a composition, by weight, of at least 10%. In one embodiment, the coating 103 is the fluorine-silicon-carbon-containing coating with fluorine, silicon, and carbon each being at a composition, by weight, of at least 10%.

As described and shown in FIG. 1, the forming device(s) receives the coated coil 101 in a flattened configuration and manipulates the material of the coated coil 101 into a shaped coated coil in a cylindrical geometry. The shaped coated coil may, for example, be any suitable geometry that, when joined at the seam, are capable of use as a conduit, pipe, tube or pipeline. The forming device(s) 111 includes any suitable arrangement of cylinders, mandrels, rollers, heaters, guides, or other metal directing devices arranged and disposed to manipulate, direct and form the coated coil 101 into a suitable cylindrical geometry. In one embodiment, forming device 111 is a bending device that continuously receives coil 101, where coil 101 is simultaneously heated with a heater, such as an induction heater, and coil 101 is directed by rollers into a cylindrical geometry. The forming device 111 forms and directs coil 101 into a cylindrical geometry that permits joining of edges of coil 101 together with welder 113.

The welder 113 is a welder capable of any suitable welding technique that joins the edges of coil 101 together. For example, welder 113 may be a MIG (Metal Inert Gas) welder, a MAG (Metal Active Gas) welder, a TIG (Tungsten Inert Gas) welder, a plasma welder, a laser welder, a submerged-arc welder, an electrode welder, or any other suitable welding apparatus capable of joining the edges of coil 101 together. The welder 113 is directed generally toward the seam corresponding the distal edges of coated coil 101. The process of welding with welder 113 results in portions of the coated coil 101 in the area of the weld formed having a reduced or eliminated coating as compared to the coating present from the coated coil 101. That is, portions of the weld formed by the welder 113 have either no coating or a have coating that has been compromised due to addition of material, exposure to high energy, movement of material, or a combination of these factors. Accordingly, the seaming operation 100 includes a step where the portion of the joined coated coil 113 is recoated (step 110) to restore or apply the coating, particularly on the inner surface of the cylinder, in order to provide continuous coating properties across the surface.

In one embodiment, the re-coating (step 110) includes applying a precursor fluid 123 to a heated zone 119 through a line 127 at a distance 125 from the welder 113. The heated zone 119 is an area of the interior portion 117 that is at or above the decomposition temperature of the precursor fluid 123. The heated zone 119 is a heated portion of the cylinder having residual heat from the welding by welder 113. The precursor fluid 123 is provided to those areas of the cylinder having temperatures sufficient to decompose the fluid and coat the cylinder in the heated zone 119. In another embodiment, the area to be coated may be heated or re-heated to the temperature at or above the decomposition temperature of the precursor fluid 123 with a heater, such as an induction heater. The heated zone 119 may be enclosed or controlled within a housing or structure that contains the precursor fluid 123 in a select location adjacent the area of the interior portion 117 of the cylinder that is to be coated. In another embodiment, the precursor fluid 123 is maintained within the interior portion 117 of the cylinder. The distance 125 is a distance from the welder 113 where the material of the cylinder to be coated is at or above the decomposition temperature of the precursor fluid 123. More specifically, distance 125 is selected such that the positioning of line 127 correlates to a position, based on the movement of the cylinder and its rate of cooling as it moves away from the welder 113, that corresponds to a temperature of the heated zone 119 that is at a temperature at or above the decomposition temperature of the precursor fluid 123. The positioning of line 127 and distance 125 may be adjusted based on ambient condition, cooling rates, speed of cylinder formation, welding technique, or other conditions that would result in the heated zone 119 being located at a distance closer or farther from welder 113. Alternatively, conditions of seaming operation 100, such as ambient conditions, active cooling/heating, speed of cylinder formation, welding technique, or other process conditions may be provided such that heated zone 119 is adjusted to area adjacent or near to line 127 and precursor fluid 123. A further embodiment includes one or more additional lines 129 with additional fluid(s) 131. The additional fluid(s) 131 may be provided to the heated zone 119 with precursor fluid 123 or may be prior to precursor fluid 123 or after precursor fluid 123 to form a multilayer coating or complex coating. The additional fluid(s) 131 may be coated onto the substrate with the same decomposition mechanism as precursor fluid 123 or via a different coating mechanism. Likewise, in other embodiment, additional fluid(s) 131 may be added to precursor fluid 123 to modify the coating composition formed. The position of the line 127 and the additional line(s) 129 is selected to provide heat, pressure, and other operational conditions to perform the re-coating 110, for example, in a manner that results in a similar composition to the coating 103.

Re-coating (step 110) is accomplished at suitable temperatures for decomposing the precursor fluid 123 to form a coating similar or identical to coating 103. Specifically, heated zone 119 is at a temperature for decomposing the precursor fluid 123. Suitable decomposition temperatures for the precursor fluid 123 includes temperatures greater than 200° C., greater than 300° C., greater than 350° C., greater than 370° C., greater than 380° C., greater than 390° C., between 300° C. and 450° C., between 350° C. and 450° C., between 380° C. and 450° C., between 300° C. and 500° C., or any suitable combination, sub-combination, range, or sub-range therein. In further embodiments, the decomposition temperature of the additional fluid(s) 131 differ or are the same, being greater than 200° C., greater than 300° C., greater than 350° C., greater than 370° C., greater than 380° C., greater than 390° C., between 300° C. and 450° C., between 350° C. and 450° C., between 380° C. and 450° C., between 300° C. and 500° C., or any suitable combination, sub-combination, range, or sub-range therein.

Suitable fluids include, but are not limited to, silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethyldimethoxysilane, dimethyldiethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctyl silane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, or a combination thereof.

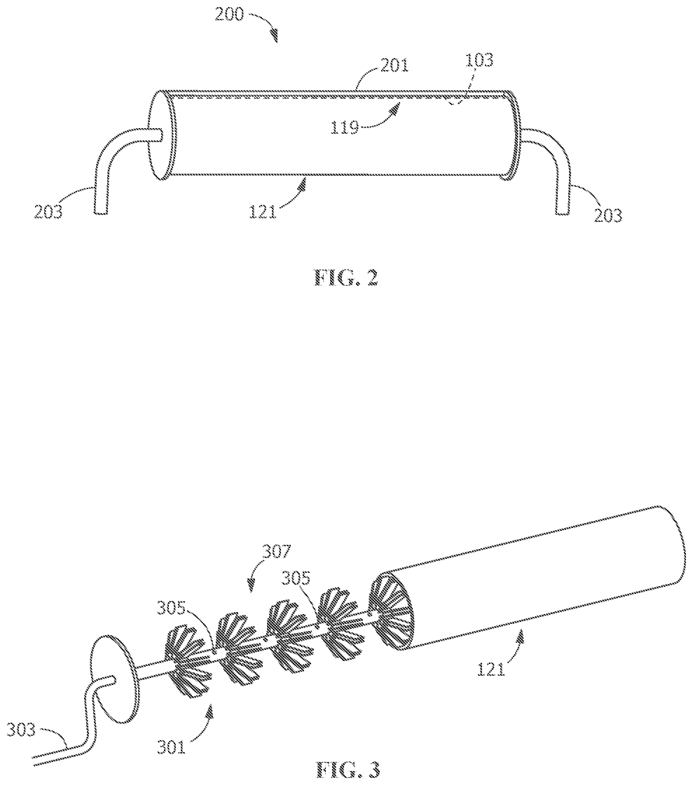

Referring to FIGS. 2-5, in some embodiments, the seaming operation 100 includes separate coating (step 200) in addition to or instead of the re-coating (step 110). The separate coating (step 200) is capable of being performed in a different facility from the seaming operation 100, in the same facility as the seaming operation 100, or on-location, for example, at a site/location of a hydrogen application.

FIG. 2 shows an embodiment with the coating 103 formed along the heated zone 119 from a localized heater 201 positioned on the exterior of the cut pipe/tube 121. The coating 103 is produced using the precursor fluid 123 and, when applicable, the additional fluid(s) 131. The precursor fluid 123 and/or the additional fluid(s) 131 are introduced and removed through one or more transfer lines 203 introduced to the cut pipe/tube 121 in an air-tight/sealed manner.

FIG. 3 shows an embodiment capable of forming the coating 103 from one or more radially-oriented heaters 301 along a pig 307 able to be positioned within the cut pipe/tube 121 and then sealed with transfer line 303 extending into the pig 307. The coating 103 is produced using the precursor fluid 123 and, when applicable, the additional fluid(s) 131. The precursor fluid 123 and/or the additional fluid(s) 131 are introduced to the pig 307 through the transfer line 303 and into apertures 305 that allow the precursor fluid 123 and/or the additional fluid(s) 131 to be heated within the cut pipe/tube 121, thereby re-applying the coating 103. In further embodiments, the radially-oriented heaters 301 are positioned to facilitate heating in specific areas where the coating 103 is to be applied/repaired, for example, weld zones, abraded regions, cut/corroded parts, or high-risk regions. In alternative embodiments, the radially-oriented heaters 301 are replaced with any suitable geometry heater.

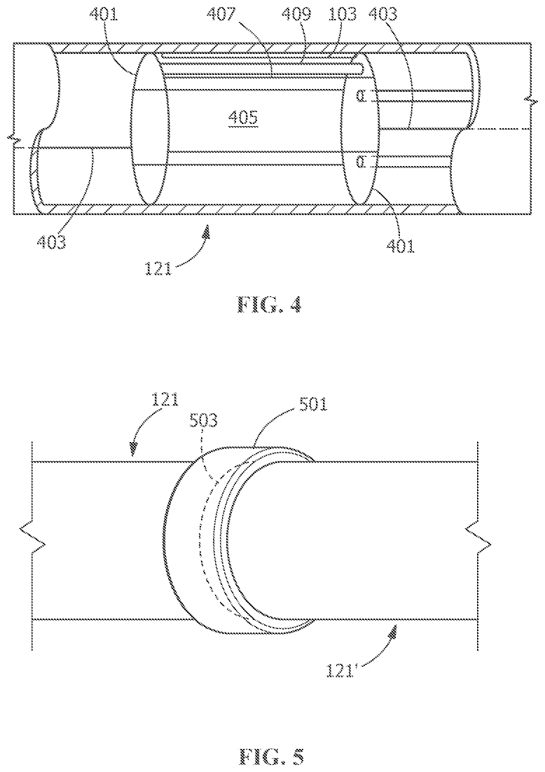

FIG. 4 shows an embodiment capable of forming the coating 103 from movable bladders 401. The movable bladders 401 include one or more tows 403 to pull the movable bladders 401 through the cut pipe/tube 121. The tows 403 are chains, cords, lines, or other suitable flexible devices that can be drawn through the cut pipe/tube 121. The movable bladder 401 forms a sealed area 405 with one or more lines 407 extending into the sealed area 405, allowing the precursor fluid 123 and/or the additional fluid(s) 131 to be introduced. The sealed area 405 includes one or more heating elements 409 to provide localized heat, facilitating deposition of the coating 103.

FIG. 5 shows an embodiment capable of forming the coating 103 from a band heater 501 positioned on a weld 503 between the cut pipe/tube 121 and an adjacent cut pipe/tube 121′. The weld 503 between the cut pipe/tube 121 forms a sealed area (not shown) allowing for the precursor fluid 123 and/or the additional fluid(s) 131 to be introduced.

In one embodiment, the hydrogen-containing fluid to be contained or conveyed by the system, according to the present disclosure, is a fluid that contains, consists essentially of or consists of dihydrogen, such as H₂ gas or liquid. In another embodiment, the hydrogen-containing fluid is a blend of dihydrogen and one or more fluids. For example, the hydrogen-containing fluid may be a fluid having greater than 10 wt % H₂, greater than 20 wt % H₂, greater than 30 wt % H₂, greater than 40 wt % H₂, greater than 50 wt % H₂, greater than 60 wt % H₂, greater than 70 wt % H₂, greater than 80 wt % H₂, greater than 90 wt % H₂, greater than 95 wt % H₂, greater than 98 wt % H₂ or any range, or sub-range therein. In another embodiment, the hydrogen-containing fluid is a hydrocarbon fluid containing dihydrogen. For example, the hydrogen-containing fluid may be a natural gas having a mixture of hydrocarbons, such as C₁-C₈ hydrocarbons, with greater than 10 wt % H₂, greater than 20 wt % H₂, greater than 30 wt % H₂, greater than 40 wt % H₂, greater than 50 wt % H₂ or any range, or sub-range therein. In other embodiments, the hydrogen-containing fluid is a syngas, process gas or byproduct gas, including hydrogen and, one or more of carbon monoxide, carbon dioxide and hydrocarbons. In one example, syngas includes 25 to 30 wt % hydrogen with carbon monoxide, carbon dioxide and methane. In addition to hydrogen, the hydrogen-containing fluid may include contaminants or secondary components, such as carbon dioxide, carbon monoxide, nitrogen, argon, oxygen, hydrogen sulfide, water vapor and/or other contaminants or secondary components.

Embodiments of the coated system capable of containing or conveying hydrogen-containing fluid, according to the disclosure, include pipelines, fittings, bolts, screws, fixtures, flanges, elbows, joints, welds, threads, wires, rings, pistons, valves, or other metal or metallic materials to be compatible with the hydrogen applications, while having a substrate that is otherwise incompatible. For example, embodiments include the hydrogen application being metal hydride storage, carbon-free production, low-carbon steel production, ammonia production, methanol production, chemical production, pressurization of hydrogen and/or hydrogen blends, depressurization of hydrogen and/or hydrogen blends, transport and/or storage of hydrogen and/or hydrogen blends. In other embodiments, the storage and/or conveying of hydrogen-containing fluids utilizing the coating system of the present disclosure may be utilized in equipment, components or systems related to catalysis, laminar flow, hydrogen refining, electrolysis, hydrogen processing/generation, hydrogen vehicle components, emissions equipment, such as NOx detection, hydrocarbon processing and other systems where hydrogen-containing fluids come into contact with hydrogen susceptible metallic materials. The coated system may include large components, including components larger than 2 meters, or 5 meters, or 10 meters, or 50 meters in length.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A coated system for containing or conveying a hydrogen-containing fluid, comprising:
a hydrogen susceptible metallic substrate; and
a coating on the hydrogen susceptible metallic substrate, the hydrogen-containing fluid being in contact with the coating;
wherein the coating reduces or eliminates the effect of hydrogen on the hydrogen susceptible metallic substrate.

2. The coated system of claim 1, wherein the effect of hydrogen on the hydrogen susceptible metallic substrate is corrosion.

3. The coated system of claim 2, wherein the effect of hydrogen on the hydrogen susceptible metallic substrate is hydride stress corrosion.

4. The coated system of claim 1, wherein the effect of hydrogen on the hydrogen susceptible metallic substrate is hydrogen embrittlement.

5. The coated system of claim 1, wherein the effect of hydrogen on the hydrogen susceptible metallic substrate is loss of storage stability.

6. The coated system of claim 1, wherein the hydrogen-containing fluid includes greater than 10 wt % H₂. The coated system of claim 1, wherein the hydrogen-containing fluid includes greater than 40 wt % H₂.

8. The coated system of claim 1, wherein the hydrogen-containing fluid includes greater than 10 wt % H₂ and a hydrocarbon.

9. The coated system of claim 1, wherein the hydrogen susceptible metallic substrate is at least a portion of a pipeline system.

10. The coated system of claim 1, wherein the hydrogen susceptible metallic substrate is at least a portion of a hydrogen storage device.

11. The coated system of claim 1, wherein the hydrogen susceptible metallic substrate is at least a portion of a vehicle.

12. The coated system of claim 1, wherein the coating is an amorphous silicon coating.

13. The coated system of claim 1, wherein the coating is a silicon-oxygen-carbon-containing coating.

14. The coated system of claim 1, wherein the coating is a silicon-nitrogen-containing coating.

15. The coated system of claim 1, wherein the hydrogen susceptible metallic substrate includes a dimension greater than 2 meters.

16. A coating process, comprising:
providing a coated coil formed from a hydrogen susceptible metallic substrate having a coating on an inside surface and an outside surface;
uncoiling the coated coil;
reshaping the coated coil with one or more forming devices to form a shaped coated coil;
welding the shaped coated coil using a welder to form a cylinder;
re-coating the cylinder on an interior portion at a heated zone;
wherein the coating on the coated coil and formed from the re-coating reduces or eliminates the effect of hydrogen on the hydrogen susceptible metallic substrate.

17. The coating process of claim 16, wherein the cylinder is at least a portion of a pipeline system.

18. The coating process of claim 16, wherein the re-coating the cylinder includes providing a precursor fluid to the heated zone.

19. The coating process of claim 18, wherein the re-coating the cylinder includes thermally decomposing the precursor fluid.

20. The coating process of claim 19, wherein the precursor fluid is selected from the group consisting of silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species, thermally-reacted materials, species capable of a recombination of carbosilyl (disilyl or trisilyl fragments), methyltrimethoxysilane, methyltriethoxysilane, dimethyldimethoxysilane, dimethyl diethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, and combinations thereof.
